(19) United States
(12) Patent Application Publication
(10) Pub. No.: US 2010/0084011 A1
(43) Pub. Date: Apr. 8, 2010

(54) ORGANIC TANDEM SOLAR CELLS

(75) Inventors: Stephen R. Forrest, Ann Arbor, MI (US); Brian E. Lassiter, Ypsilanti, MI (US); Guodan Wei, Ann Arbor, MI (US)

Correspondence Address: MCDERMOTT WILL & EMERY LLP, 2049 CENTURY PARK EAST, 38th Floor, LOS ANGELES, CA, 90067-3208, US

(73) Assignee: THE REGENTS OF THE UNIVERSITY OF MICHIGAN, Ann Arbor, MI (US)

(21) Appl. No.: 12/567,633

(22) Filed: Sep. 25, 2009

Related U.S. Application Data
(60) Provisional application No. 61/100,583, filed on Sep. 26, 2008.
(60) Provisional application No. 61/118,529, filed on Nov. 28, 2008.

(51) Int. Cl. H01L 51/44; H01L 51/48

(52) U.S. Cl. 136/255; 136/263; 438/82; 324/72; 257/E51.012

(57) ABSTRACT

There is disclosed an organic photovoltaic device comprising two or more organic photoactive regions located between a first electrode and a second electrode, wherein each of the organic photoactive regions comprise a donor, and an acceptor, and wherein the organic photovoltaic device comprises at least one exciton blocking layer, and at least one charge recombination layer, or charge transfer layer between the two or more photoactive regions. It has been discovered that a high open circuit voltage can been obtained for organic tandem solar cells according to this disclosure. Methods of making and methods of using are also disclosed.

### CROSS-REFERENCE TO RELATED APPLICATIONS

This application is based upon and claims priority to U.S. Provisional Patent Application No. 61/100,583, entitled “Organic Tandem Solar Cells,” filed Sep. 26, 2008, and U.S. Provisional Patent Application No. 61/118,529, entitled “Tandem Organic Solar Cells Incorporating CuPc and SubPc as Donor Materials,” filed Nov. 28, 2008, the entire contents of both of which are incorporated herein by reference.

### JOINT RESEARCH AGREEMENT

The claimed invention was made by, on behalf of, and/or in connection with the following parties to a joint university-corporation research agreement: The Regents of the University of Michigan and Global Photonic Energy Corporation. The agreement was in effect on and before the date the claimed invention was made, and the claimed invention was made as a result of activities undertaken within the scope of the agreement.

### TECHNICAL FIELD

The present disclosure generally relates to organic tandem solar cells. Methods of making such devices, which may include at least one sublimation step for depositing the squaraine compound, are also disclosed.

### BACKGROUND

Optoelectronic devices rely on the optical and electronic properties of materials to either produce or detect electromagnetic radiation electronically or to generate electricity from ambient electromagnetic radiation.

Photosensitive optoelectronic devices convert electromagnetic radiation into electricity. Solar cells, also called photovoltaic (PV) devices, are a type of photosensitive optoelectronic device that are specifically used to generate electrical power. PV devices, which may generate electrical energy from light sources other than sunlight, can be used to drive power consuming loads to provide, for example, lighting, heating, or to power electronic circuitry or devices such as calculators, radios, computers or remote monitoring or communications equipment. These power generation applications also often involve the charging of batteries or other energy storage devices so that operation may continue when direct illumination from the sun or other light sources is not available, or to balance the power output of the PV device with a specific application's requirements. As used herein the term “resistive load” refers to any power consuming or storing circuit, device, equipment or system.

Another type of photosensitive optoelectronic device is a photoconductor cell. In this function, signal detection circuitry monitors the resistance of the device to detect changes due to the absorption of light.

Another type of photosensitive optoelectronic device is a photodetector. In operation, a photodetector is used in conjunction with a current detecting circuit which measures the current generated when the photodetector is exposed to electromagnetic radiation and may have an applied bias voltage. A detecting circuit as described herein is capable of providing a bias voltage to a photodetector and measuring the electronic response of the photodetector to electromagnetic radiation.

These three classes of photosensitive optoelectronic devices may be characterized according to whether a rectifying junction as defined below is present and also according to whether the device is operated with an external applied voltage, also known as a bias or bias voltage. A photoconductor cell does not have a rectifying junction and is normally operated with a bias. A PV device has at least one rectifying junction and is operated with no bias. A photodetector has at least one rectifying junction and is usually, but not always, operated with a bias. Typically, a photovoltaic cell provides power to a circuit, device or equipment. A photodetector or photoconductor provides a signal or current to control detection circuitry, or the output of information from the detection circuitry but does not provide power to the circuitry, device or equipment.

Traditionally, photosensitive optoelectronic devices have been constructed of a number of inorganic semiconductors, e.g., crystalline, polycrystalline and amorphous silicon, gallium arsenide, cadmium telluride and others. Herein the term “semiconductor” denotes materials which can conduct electricity when charge carriers are induced by thermal or electromagnetic excitation. The term “photoconductive” generally relates to the process in which electromagnetic radiant energy is absorbed and thereby converted to excitation energy of electric charge carriers so that the carriers can conduct, i.e., transport, electric charge in a material. The terms “photoconductor” and “photoconductive material” are used herein to refer to semiconductor materials which are chosen for their property of absorbing electromagnetic radiation to generate electric charge carriers.

PV devices may be characterized by the efficiency with which they can convert incident solar power to useful electric power. Devices utilizing crystalline or amorphous silicon dominate commercial applications, and some have achieved efficiencies of 23% or greater. However, efficient crystalline-based devices, especially of large surface area, are difficult and expensive to produce due to the problems inherent in producing large crystals without significant efficiency-degrading defects. On the other hand, high efficiency amorphous silicon devices still suffer from problems with stability. Present commercially available amorphous silicon cells have stabilized efficiencies between 4 and 8%. More recent efforts have focused on the use of organic photovoltaic cells to achieve acceptable photovoltaic conversion efficiencies with economical production costs.

PV devices may be optimized for maximum electrical power generation under standard illumination conditions (i.e., Standard Test Conditions which are 1000 W/m², AM1.5 spectral illumination), for the maximum product of photocurrent times photovoltage. The power conversion efficiency of such a cell under standard illumination conditions depends on the following three parameters: (1) the current under zero bias, i.e., the short-circuit current I_{SC}, in Amperes (2) the photovoltage under open circuit conditions, i.e., the open circuit voltage V_{OC}, in Volts and (3) the fill factor, ff.

PV devices produce a photo-generated current when they are connected across a load and are irradiated by light. When irradiated under infinite load, a PV device generates its maximum possible voltage, V open-circuit, or V_{OC}. When irradiated with its electrical contacts shorted, a PV device generates its maximum possible current, I short-circuit, or I_{SC}. When actually used to generate power, a PV device is connected to a finite resistive load and the power output is given by the product of the current and voltage, I×V. The maximum total power generated by a PV device is inherently incapable of exceeding the product, I_{SC}×V_{OC}. When the load value is optimized for maximum power extraction, the current and voltage have the values, Iₘₐₓ and Vₘₐₓ, respectively.

A figure of merit for PV devices is the fill factor, FF, defined as:

FF={IₘₐₓVₘₐₓ}/{I_{SC}V_{OC}} (1)

where FF is always less than 1, as I_{SC} and V_{OC} are never obtained simultaneously in actual use. Nonetheless, as FF approaches 1, the device has less series or internal resistance and thus delivers a greater percentage of the product of I_{SC} and V_{OC} to the load under optimal conditions. Where P_{inc} is the power incident on a device, the power efficiency of the device, η_{P}, may be calculated by:

η_{P}=FF*(I_{SC}*V_{OC})/P_{inc}

When electromagnetic radiation of an appropriate energy is incident upon a semiconductive organic material, for example, an organic molecular crystal (OMC) material, or a polymer, a photon can be absorbed to produce an excited molecular state. This is represented symbolically as S₀+hvψS₀*. Here S₀ and S₀* denote ground and excited molecular states, respectively. This energy absorption is associated with the promotion of an electron from a bound state in the HOMO energy level, which may be a B-bond, to the LUMO energy level, which may be a B*-bond, or equivalently, the promotion of a hole from the LUMO energy level to the HOMO energy level. In organic thin-film photoconductors, the generated molecular state is generally believed to be an exciton, i.e., an electron-hole pair in a bound state which is transported as a quasi-particle. The excitons can have an appreciable life-time before geminate recombination, which refers to the process of the original electron and hole recombining with each other, as opposed to recombination with holes or electrons from other pairs. To produce a photocurrent the electron-hole pair becomes separated, typically at a donor-acceptor interface between two dissimilar contacting organic thin films. If the charges do not separate, they can recombine in a geminant recombination process, also known as quenching, either radiatively, by the emission of light of a lower energy than the incident light, or non-radiatively, by the production of heat. Either of these outcomes is undesirable in a photosensitive optoelectronic device.

Electric fields or inhomogeneities at a contact may cause an exciton to quench rather than dissociate at the donor-acceptor interface, resulting in no net contribution to the current. Therefore, it is desirable to keep photogenerated excitons away from the contacts. This has the effect of limiting the diffusion of excitons to the region near the junction so that the associated electric field has an increased opportunity to separate charge carriers liberated by the dissociation of the excitons near the junction.

To produce internally generated electric fields which occupy a substantial volume, the usual method is to juxtapose two layers of material with appropriately selected conductive properties, especially with respect to their distribution of molecular quantum energy states. The interface of these two materials is called a photovoltaic heterojunction. In traditional semiconductor theory, materials for forming PV heterojunctions have been denoted as generally being of either n or p type. Here n-type denotes that the majority carrier type is the electron. This could be viewed as the material having many electrons in relatively free energy states. The p-type denotes that the majority carrier type is the hole. Such material has many holes in relatively free energy states. The type of the background, i.e., not photo-generated, majority carrier concentration depends primarily on unintentional doping by defects or impurities. The type and concentration of impurities determine the value of the Fermi energy, or level, within the gap between the highest occupied molecular orbital (HOMO) energy level and the lowest unoccupied molecular orbital (LUMO) energy level, called the HOMO-LUMO gap. The Fermi energy characterizes the statistical occupation of molecular quantum energy states denoted by the value of energy for which the probability of occupation is equal to ½. A Fermi energy near the LUMO energy level indicates that electrons are the predominant carrier. A Fermi energy near the HOMO energy level indicates that holes are the predominant carrier. Accordingly, the Fermi energy is a primary characterizing property of traditional semiconductors and the prototypical PV heterojunction has traditionally been the p-n interface.

The term “rectifying” denotes, inter alia, that an interface has an asymmetric conduction characteristic, i.e., the interface supports electronic charge transport preferably in one direction. Rectification is associated normally with a built-in electric field which occurs at the heterojunction between appropriately selected materials.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

In the context of organic materials, the terms “donor” and “acceptor” refer to the relative positions of the HOMO and LUMO energy levels of two contacting but different organic materials. This is in contrast to the use of these terms in the inorganic context, where “donor” and “acceptor” may refer to types of dopants that may be used to create inorganic n- and p-types layers, respectively. In the organic context, if the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

A significant property in organic semiconductors is carrier mobility. Mobility measures the ease with which a charge carrier can move through a conducting material in response to an electric field. In the context of organic photosensitive devices, a layer including a material that conducts preferentially by electrons due to a high electron mobility may be referred to as an electron transport layer, or ETL. A layer including a material that conducts preferentially by holes due to a high hole mobility may be referred to as a hole transport layer, or HTL. In one embodiment, an acceptor material is an ETL and a donor material is a HTL.

Conventional inorganic semiconductor PV cells employ a p-n junction to establish an internal field. Early organic thin film cell, such as reported by Tang, Appl. Phys Lett. 48, 183 (1986), contain a heterojunction analogous to that employed in a conventional inorganic PV cell. However, it is now recognized that in addition to the establishment of a p-n type junction, the energy level offset of the heterojunction also plays an important role.

The energy level offset at the organic D-A heterojunction is believed to be important to the operation of organic PV devices due to the fundamental nature of the photogeneration process in organic materials. Upon optical excitation of an organic material, localized Frenkel or charge-transfer excitons are generated. For electrical detection or current generation to occur, the bound excitons must be dissociated into their constituent electrons and holes. Such a process can be induced by the built-in electric field, but the efficiency at the electric fields typically found in organic devices (F ˜10⁶ V/cm) is low. The most efficient exciton dissociation in organic materials occurs at a donor-acceptor (D-A) interface. At such an interface, the donor material with a low ionization potential forms a heterojunction with an acceptor material with a high electron affinity. Depending on the alignment of the energy levels of the donor and acceptor materials, the dissociation of the exciton can become energetically favorable at such an interface, leading to a free electron polaron in the acceptor material and a free hole polaron in the donor material.

Organic PV cells have many potential advantages when compared to traditional silicon-based devices. Organic PV cells are light weight, economical in materials use, and can be deposited on low cost substrates, such as flexible plastic foils. However, organic PV devices typically have relatively low power conversion efficiency, being on the order of 1% or less. This is, in part, thought to be due to the second order nature of the intrinsic photoconductive process. That is, carrier generation requires exciton generation, diffusion and ionization or collection. There is an efficiency η associated with each of these processes. Subscripts may be used as follows: P for power efficiency, EXT for external quantum efficiency, A for photon absorption exciton generation, ED for diffusion, CC for collection, and INT for internal quantum efficiency. Using this notation:

η_{P}˜η_{EXT}=η_{A}*η_{ED}*η_{CC}

η_{EXT}=η_{A}*η_{INT}

The diffusion length (L_{D}) of an exciton is typically much less (L_{D}˜50 Å) than the optical absorption length (˜500 Å), requiring a trade off between using a thick, and therefore resistive, cell with multiple or highly folded interfaces, or a thin cell with a low optical absorption efficiency.

Typically, when light is absorbed to form an exciton in an organic thin film, a singlet exciton is formed. By the mechanism of intersystem crossing, the singlet exciton may decay to a triplet exciton. In this process, energy is lost which will result in a lower efficiency for the device. If not for the energy loss from intersystem crossing, it would be desirable to use materials that generate triplet excitons, as triplet excitons generally have a longer lifetime, and therefore a longer diffusion length, than do singlet excitons.

Through the use of an organometallic material in the photoactive region, the devices of the present invention may efficiently utilize triplet excitons. We have found that the singlet-triplet mixing may be so strong for organometallic compounds, that the absorptions involve excitation from the singlet ground states directly to the triplet excited states, eliminating the losses associated with conversion from the singlet excited state to the triplet excited state. The longer lifetime and diffusion length of triplet excitons in comparison to singlet excitons may allow for the use of a thicker photoactive region, as the triplet excitons may diffuse a greater distance to reach the donor-acceptor heterojunction, without sacrificing device efficiency.

Solar cells based on organic materials are promising candidates for ubiquitous solar energy generation due to their potential for low-cost, large area commercial production. Recently, tandem structures which incorporate two or more individual cells have displayed increased device performance.

Organic tandem solar cells with two or more subcells electrically coupled in series have the unique advantage that the open circuit voltage (V_{OC}) is increased to the sum of the V_{OC} of the individual subcells. Previously, the same small molecule organic materials have been utilized in the front and back cells.

In certain circumstances, two different donor materials have been employed in each subcell, enabling absorption over a broad range of photon energies in the solar emission spectrum. It has been demonstrated that a V_{OC} as high as 0.98 V can been obtained for a single junction cell with chloro[Subphthalocyanine]boron(III) (SubPc) as a donor material and fullerene as an acceptor material.

### SUMMARY

There is disclosed an organic photovoltaic device comprising two or more organic photoactive regions located between a first electrode and a second electrode, wherein each of the organic photoactive regions comprise a donor and an acceptor. In one embodiment, the organic photovoltaic device comprises at least one exciton blocking layer, and at least one charge recombination layer or charge transfer layer between the two or more photoactive regions.

In one embodiment, at least one of the at least two photoactive regions comprises a donor-acceptor heterojunction formed by a planar, bulk, mixed, hybrid-planar-mixed or nanocrystalline bulk heterojunction. For example, the heterojunction may comprise mixtures of two or more materials chosen from: subphthalocyanine (SubPc), C₆₀, C₇₀, squaraine, copper phthalocyanine (CuPc), tin phthalocyanine (SnPc), chloroaluminum phthalocyanine (ClAlPc), and diindenoperylene (DIP).

Tandem cells modeled and made using careful design of layer thickness, material selection, film order, and film crystallinity resulted in devices that could exceed 11% device performance. As shown herein, tandem cells using SubPc as a donor in both cells incorporating various thickness, material selection, film order, and film crystallinity are created.

Additionally, SubPc and copper phthalocyanine (CuPc) have complementary absorption ranges of 500-600 nm and 600-700 nm respectively. As shown herein, tandem cells using SubPc and CuPc as the donors in tandem solar cells result in improved uniformity of the spectral response across the visible region compared to that of an individual subcell. Thus, when the layer thicknesses of SubPc and CuPc are optimum, the absorption peak in the front cell and back cell will be located in the different wavelength region which will balance the photocurrent in these two subcells.

Methods of making the disclosed devices and methods of using them are also disclosed.

### BRIEF DESCRIPTION OF THE DRAWINGS FIGURES

FIG. 1. Is a graph showing the absorption coefficients of various organic semiconducting materials.

FIG. 2. Bottom: plot of the extinction coefficient for certain active materials utilized in the solar cells. Top: relationship of those active materials to the AM1.5G solar spectrum.

FIG. 3. Is a contour plot representing optimization of a stacked organic tandem solar cell under 100 mW/cm², AM1.5G illumination conditions for constant J_{sc} (mA/cm²). The device structure is glass/1500 Å ITO/x Å SubPc/x Å C₆₀/5 Å Ag/y Å SubPc/y Å C₆₀/100 Å BCP/800 Å Al.

FIG. 4. Is a contour plot representing optimization of a stacked organic tandem solar cell under 100 mW/cm², AM1.5G illumination conditions for constant J_{sc} (mA/cm²). The device structure is glass/1500 Å ITO/x Å SubPc/x Å C₆₀/5 Å Ag/y Å CuPc/y Å C₆₀/100 Å BCP/800 Å Ag.

FIG. 5. Is a contour plot of the normalized optical field within the modeled tandem cell of the following: glass/1500 Å ITO/50 Å MoO₃/145 Å SubPc/180 Å C₆₀/50 Å PTCBI/10 Å Ag/25 Å MoO₃/120 Å CuPc/100 Å C₆₀/80 Å BCP/1 k Å Ag. Circled areas represent the absorption region for the materials.

FIG. 6. Is a contour plot of the normalized optical field within the modeled tandem cell of the following: glass/1500 Å ITO/175 Å CuPc/100 Å C₆₀/50 Å PTCBI/10 Å Ag/25 Å MoO₃/105 Å SubPc/345 Å C₆₀/80 Å BCP/1 k Å Ag. Circled areas represent the absorption region for the materials.

FIG. 7. Is a plot of the change in modeled normalized photocurrent when varying the normalized thicknesses of the photoactive layers in a tandem device. The structure is glass/1500 Å ITO/175 Å CuPc/100 Å C₆₀/50 Å PTCBI/10 Å Ag/25 Å MoO₃/105 Å SubPc/345 Å C₆₀/80 Å BCP/1 k Å Ag.

FIG. 8. Is a contour plot representing optimization of a nanocrystalline stacked organic tandem solar cell under 100 mW/cm², AM1.5G illumination conditions for constant power efficiency (%). The device structure is glass/1500 Å ITO/50 Å SubPc/x Å SubPc:C₆₀(nano)/400 Å C₆₀/5 Å Ag/100 Å CuPc/y Å CuPc:C₆₀(nano)/200 Å C₆₀/100 Å BCP/800 Å Ag.

FIG. 9. Is a calculated contour plot of the efficiency of a tandem solar cell with SubPc/C₆₀ planar heterojunction front and back subcells as a function of exciton diffusion length and series resistance. It is assumed that the ideality factor n is equal to two.

FIG. 10. Is a calculated contour plot of the efficiency of a tandem device with a nanocrystalline SubPc/C₆₀ front cell and nanocrystalline CuPc/C₆₀ back cell as a function of changes in exciton diffusion length and series resistance. An ideality factor of 2 is assumed. The modeled structure is shown on the right.

FIG. 11. Is the performance of front, back, and unoptimized tandem devices with a front cell containing SubPc and a back cell containing CuPc. Linear (upper left) and logarithmic (lower left) J-V curves at one sun (100 mW/cm₂) are plotted, along with experimental (upper right) and modeled (lower right) external quantum efficiencies. The inset shows the device structures.

FIG. 12. Is the performance of front, back, and unoptimized tandem devices with a front cell containing SubPc and a back cell containing SQ. Linear (upper left) and logarithmic (lower left) J-V curves at one sun (100 mW/cm₂) are plotted, along with experimental (upper right) external quantum efficiencies. The device structures are shown in the lower right.

FIG. 13. Device structure and J-V curves for the tandem device under AM1.5G illumination. 100 mW/cm² corresponds to 1 sun intensity.

FIG. 14. Device structures for the front (left) and back (right) cells.

FIG. 15. Plot showing comparison of Voc between the tandem (squares), front (circles), and back (triangles). The sum of the Voc for the front and back cells is also displayed (stars).

FIG. 16. Normalized EQE of the tandem (squares), front (circles), and back (triangles) cells respectively. The tandem cell shows both the high peak of SubPc and the extended shoulder of CuPc.

FIG. 17. Various plots showing the experimentally grown device of the following: glass/1500 Å ITO/50 Å MoO₃/10 Å NPD/130 Å SuPc/170 Å C₆₀/50 Å PTCBI/8 Å Ag/25 Å MoO₃/75 Å CuPc/230 Å C₆₀/70 Å BCP/1 k Å Ag. Clockwise from the upper left: the structure of the device, log and linear J-V curves at varying light intensities, and device performance plotted versus incident light power.

FIG. 18. Plot showing comparison of the J-V curve of the front, back, and tandem cell from FIG. 17.

FIG. 19. Modeled EQE of the front and back cells in the tandem structure of the following: glass/1500 Å ITO/50 Å MoO₃/10 Å NPD/130 Å SuPc/170 Å C₆₀/50 Å PTCBI/8 Å Ag/25 Å MoO₃/75 Å CuPc/230 Å C₆₀/70 Å BCP/1 k Å Ag.

FIG. 20. Comparison of the EQE of the individual front and back cells from FIG. 19.

### DETAILED DESCRIPTION OF THE INVENTION

There is disclosed an organic photovoltaic device comprising two or more organic photoactive regions located between a first electrode and a second electrode, wherein each of the organic photoactive regions comprise a donor, and an acceptor. In one embodiment, the organic photovoltaic device comprises at least one exciton blocking layer, and at least one charge recombination layer, or charge transfer layer between the two or more photoactive regions.

Representative embodiments may also comprise transparent charge transfer layers or charge recombination layers. As described herein charge transfer layers are distinguished from acceptor and donor layers by the fact that charge transfer layers are frequently, but not necessarily, inorganic (often metals) and they may be chosen not to be photoconductively active. The term “charge transfer layer” is used herein to refer to layers similar to but different from electrodes in that a charge transfer layer only delivers charge carriers from one subsection of an optoelectronic device to the adjacent subsection. The term “charge recombination layer” is used herein to refer to layers similar to but different from electrodes in that a charge recombination layer allows for the recombination of electrons and holes between tandem photosensitive devices and may also enhance internal optical field strength near one or more active layers. A charge recombination layer can be constructed of semi-transparent metal nanoclusters, nanoparticle or nanorods as described in U.S. Pat. No. 6,657,378, incorporated herein by reference in its entirety.

In one embodiment, at least one electrode comprises transparent conducting oxides, such as indium tin oxide (ITO), tin oxide (TO), gallium indium tin oxide (GITO), zinc oxide (ZO), and zinc indium tin oxide (ZITO), or transparent conductive polymers, such as polyanaline (PANI).

When the electrode is a cathode, it may comprise a metal substitute, a non-metallic material or a metallic material, such as one chosen from Ag, Au, Ti, Sn, and Al.

In one embodiment, the charge transfer layer or charge recombination layer may be comprised of Al, Ag, Au, MoO₃, Li, LiF, Sn, Ti, WO₃, indium tin oxide (ITO), tin oxide (TO), gallium indium tin oxide (GITO), zinc oxide (ZO), or zinc indium tin oxide (ZITO). In another embodiment, the charge recombination layer may be comprised of metal nanoclusters, nanoparticles, or nanorods.

With regard to donor materials that may be used in the present disclosure, non-limiting mention is made to those chosen from subphthalocyanine (SubPc), copper phthalocyanine (CuPc), chloroaluminium phthalocyanine (ClAlPc), tin phthalocyanine (SnPc), pentacene, tetracene, diindenoperylene (DIP), and squaraine (SQ).

Non-limiting embodiments of the squaraine compound that may be used are those chosen from 2,4-Bis [4-(N,N-dipropylamino)-2,6-dihydroxyphenyl; 2,4-Bis[4-(N,N-diisobutylamino)-2,6-dihydroxyphenyl; and salts thereof.

In one embodiment, the donor material may be doped with a high mobility material, such as one that comprises pentacene or metal nanoparticles.

In one embodiment, each of the organic photoactive regions described herein may comprise a donor that exhibits complementary absorption ranges with the donor of at least one other organic photoactive region.

With regard to acceptor materials that may be used in the present disclosure, non-limiting mention is made to those chosen from C₆₀, C₇₀, 3,4,9,10-perylenetetracarboxylicbis-benzimidazole (PTCBI), Phenyl-C₆₁-Butyric-Acid-Methyl Ester ([60]PCBM), Phenyl-C₇₁-Butyric-Acid-Methyl Ester ([70]PCBM), Thienyl-C₆₁-Butyric-Acid-Methyl Ester ([60]ThCBM), and hexadecafluorophthalocyanine (F₁₆CuPc).

With regard to materials that may be used as an exciton blocking layer, non-limiting mention is made to those chosen from bathocuproine (BCP), bathophenanthroline (BPhen), 3,4,9,10-perylenetetracarboxylicbis-benzimidazole (PTCBI), 1,3,5-tris(N-phenylbenzimidazol-2-yl)benzene (TPBi), tris(acetylacetonato) ruthenium(III) (Ru(acaca)₃), and aluminum(III)phenolate (Alq₂ OPH).

In one embodiment, at least one of the at least two photoactive regions comprises a donor-acceptor heterojunction formed by a planar, bulk, mixed, hybrid-planar-mixed or nanocrystalline bulk heterojunction. For example, the heterojunction may comprise mixtures of two or more materials chosen from: subphthalocyanine (SubPc), C₆₀, C₇₀, squaraine, copper phthalocyanine (CuPc), tin phthalocyanine (SnPc), chloroaluminum phthalocyanine (ClAlPc), and diindenoperylene (DIP).

Non-limiting examples of mixtures of materials that may be used to form heterojunctions include:

subphthalocyanine (SubPc)/C₆₀;

subphthalocyanine (SubPc)/C₇₀;

squaraine/C₆₀;

copper phthalocyanine (CuPc)/C₆₀;

copper phthalocyanine (CuPc)/tin phthalocyanine (SnPc)/C₆₀; or

diindenoperylene (DIP)/C₇₀;

aluminum-chlorophthalocyanine (AlClPc)/C₆₀; and

aluminum-chlorophthalocyanine (AlClPc)/C₇₀.

In one embodiment, the photoactive layers described herein further comprises a buffer material, such as WO₃, V₂O₅, MoO₃, and other oxides.

In making the organic photovoltaic device described herein, one or more organic layers may be deposited by vacuum thermal evaporation, organic vapor-jet printing or organic vapor phase deposition. Alternatively, the organic layers may be deposited using a solution processing approach, such as by doctor-blading, spin coating, or inkjet printing.

The thickness of the organic layers used in the organic photovoltaic device described herein may range from 25-1200 \acute{Å}, such as from 50-950 \acute{Å}, or even from 60-400 \acute{Å}.

In one embodiment, the organic layer is crystalline, and may be crystalline over an extended area, such as from 100 nm to 1000 nm, or even over a range from 10 nm to 1 cm.

The organic photovoltaic device described herein may display an open-circuit voltage (V_{oc}) in a range up to 2.2 V, such as 1.57 V, and a power efficiency (ηₚ) greater than 2%, even greater than 10%. In one embodiment, the organic photovoltaic device described herein may exhibit a power efficiency greater than 11%.

In one embodiment, the organic photovoltaic device described herein may comprise three or more organic photoactive regions, each of the organic photoactive regions comprising a donor and an acceptor. In one embodiment, the device further comprising at least one exciton blocking layer, charge recombination layer or charge transfer layer and optionally comprising a buffer layer.

In another embodiment, the organic photovoltaic device described herein comprises two or more organic photoactive regions located between a first electrode and a second electrode,

wherein each of the organic photoactive regions comprise:

a donor comprising a material chosen from subphthalocyanine (SubPc), copper phthalocyanine (CuPc), chloroaluminium phthalocyanine (ClAlPc), tin phthalocyanine (SnPc), pentacene, tetracene, diindenoperylene (DIP), squaraine (SQ), zinc phthalocyanine (ZnPc), and lead phthalocyanine (PbPc);

an acceptor comprising a material chosen from C₆₀, C₇₀, 3,4,9,10-perylenetetracarboxylicbis-benzimidazole (PTCBI), Phenyl-C₆₁-Butyric-Acid-Methyl Ester, ([60]PCBM), Phenyl-C₇₁-Butyric-Acid-Methyl Ester ([70]PCBM), Thienyl-C₆₁-Butyric-Acid-Methyl Ester ([60]ThCBM), and hexadecafluorophthalocyanine (F₁₆CuPc);

an exciton blocking layer comprising a material chosen from WO₃, MoO₃, bathocuproine (BCP), bathophenanthroline (BPhen), 3,4,9,10-perylenetetracarboxylicbis-benzimidazole (PTCBI), and 1,3,5-tris(N-phenylbenzimidazol-2-yl)benzene (TPBi), ruthenium(III) (Ru(acaca)₃);

a charge recombination layer or charge transfer layer comprising a material chosen from Al, Ag, Au, MoO₃, and WO₃, and optionally a buffer layer comprising MoO₃,

wherein at least one of the electrodes is an anode that comprises indium tin oxide (ITO) and at least one of the electrodes is a cathode that comprises a material chosen from Ag, Au, and Al.

In this embodiment, like the other embodiments, at least one of the photoactive regions may comprise a donor-acceptor heterojunction formed by a planar, bulk, mixed, hybrid-planar-mixed or nanocrystalline bulk heterojunction. As previously stated, the heterojunction comprises mixtures of two or more materials chosen from: subphthalocyanine (SubPc), C₆₀, C₇₀, squaraine, copper phthalocyanine (CuPc), tin phthalocyanine (SnPc), diindenoperylene (DIP), and aluminum chlorophthalocyanine (AlClPc).

Non-limiting examples of mixtures of materials that may be used to form heterojunctions include:

subphthalocyanine (SubPc)/C₆₀;

subphthalocyanine (SubPc)/C₇₀;

squaraine/C₆₀;

copper phthalocyanine (CuPc)/C₆₀;

copper phthalocyanine (CuPc)/tin phthalocyanine (SnPc)/C₆₀,

diindenoperylene (DIP)/C₇₀;

aluminum chlorophthalocyanine (AlClPc)/C₆₀,

aluminum chlorophthalocyanine (AlClPc)/C₇₀; or

copper phthalocyanine (CuPc)/aluminum chlorophthalocyanine (AlClPc)/C₆₀.

There is also disclosed a method for producing an organic photovoltaic device, that comprises:

depositing a first electrode onto a substrate;

depositing a first photoactive region onto the first electrode;

depositing a first charge recombination layer or charge transfer layer onto the first photoactive region;

depositing a second photoactive region onto the first charge recombination layer or charge transfer layer; and

depositing a second electrode onto the second photoactive region;

wherein the first organic photoactive region comprises a first donor and a first acceptor,

wherein the second organic photoactive region comprises a second donor and a second acceptor,

wherein an exciton blocking layer is deposited over at least one photoactive region and

wherein a charge recombination layer, charge transfer layer, or electrode is deposited between each photoactive region.

In addition, there is disclosed a method for generating and/or measuring electricity or an electric signal that comprises providing light to the organic photovoltaic devices described herein.

Utilizing the optimization method described above, the inventors have found that it is possible to fabricate many different types of tandem solar cells. One non-limiting structure is the following: glass/1500 Å ITO/x₁ Å donor 1/x₂ Å acceptor 1/x₃ Å exciton blocker/x₄ Å charge recombination layer or charge transfer layer/y₁ Å donor 2/y₂ Å acceptor 2/y₃ Å exciton blocker/y₄ Å metal cathode. Another non-limiting structure is the following: glass/1500 Å ITO/x_{1′} Å buffer 1/x₁ Å donor 1/x₂ Å acceptor 1/x₃ Å exciton blocker/x₄ Å charge recombination layer or charge transfer layer/y_{1′} Å buffer 2/y₁ Å donor 2/y₂ Å acceptor 2/y₃ Å exciton blocker/y₄ Å metal cathode.

Donor materials include SubPc, CuPc, chloroaluminum phthalocyanine (ClAlPc), tin phthalocyanine (SnPc), pentacene, tetracene, diindenoperylene (DIP), squaraine (SQ), and many others. Acceptor materials include the fullerene family (C₆₀) C₇₀, C₈₀, C₈₄, and others), 3,4,9, 10-perylenetetracarboxylicbis-benzimidazole (PTCBI), hexadecafluorophthalocyanine (F₁₆CuPc), and others. Exciton blocking layers include bathocuproine (BCP), bathophenanthroline (BPhen), PTCBI, 1,3,5-tris(N-phenylbenzimidazol-2-yl)benzene (TPBi), and others.

The charge recombination layer or charge transfer layer between cells can comprise Al, Ag, Au, MoO₃, WO₃, including nanocluster thereof and others, while the cathode can comprise Al, Ag, Au, or other metals.

The following U.S. patents are herein incorporated by reference for their teachings of materials, such as donors, acceptors, blocking layers, charge recombination layers, charge transfer layers, other layers and the like, that can be used in the inventive organic tandem devices: U.S. Pat. Nos. 6,657,378; 6,278,055; and 7,326,955.

The buffer can be chosen from metal oxides such as WO₃, V₂O₅, MoO₃, and others or organic materials such as NPD, Alq₃, or others.

Examples of possible planar heterojunction tandem structures are shown in Table 1. Tandem devices of more than two subcells are also possible by repeating the donor/acceptor/exciton blocker/charge recombination layer or charge transfer layer sequence.

TABLE 1
Example structures for planar heterojunction tandem solar cells.

| Donor | Acceptor | Blocking | Layer | Donor | Acceptor | Blocking | Cathode |
|---|---|---|---|---|---|---|---|
| CuPc | C₆₀ | PTCBl | Ag/MoO₃ | SubPc | C₇₀ | BCP | Ag |
| CuPc | C₇₀ | PTCBl | Ag/WO₃ | SubPc | C₆₀ | PTCBl | Al |
| SubPc | C₆₀ | PTCBl | Ag | CuPc | C₆₀ | BCP | Ag |
| SubPc | C₇₀ | PTCBl | Ag | CuPc | C₆₀ | BPhen | Au |
| SubPc | C₆₀ | BCP | Ag | DlP | C₆₀ | BCP | Ag |
| SQ | C₆₀ | BCP | Ag | SubPc | C₇₀ | PTCBl | Al |
| ClAlPc | C₆₀ | BCP | WO₃ | SubPc | C₇₀ | BCP | Al |
| CuPc | F₁₆CuPc | BPhen | MoO₃ | SubPc | C₇₀ | TPBi | Al |

Layer = Charge transfer layer or Charge recombination layer

Examples of devices containing three planar heterojunction subcells are shown in Table 2.

TABLE 2
Example structures for planar heterojunction solar cells with three subcells.

| Donor | A | B | L | Donor | A | B | L | Donor | A | B | C |
|---|---|---|---|---|---|---|---|---|---|---|---|
| SubPc | C₆₀ | BCP | Ag | CuPc | F₁₆CuPc | BCP | Ag | SQ | C₇₀ | BCP | Al |
| SubPc | C₇₀ | BPhen | MoO₃ | DlP | C₆₀ | PTCBl | WO₃ | ClAlPc | C₆₀ | BCP | Ag |
| DlP | C₆₀ | PTCBl | Ag | SubPc | C₇₀ | BCP | Ag | CuPc | C₆₀ | BCP | Ag |

A = Acceptor layer
B = Blocking layer
C = Cathode
L = Charge transfer Layer or Charge Recombination Layer

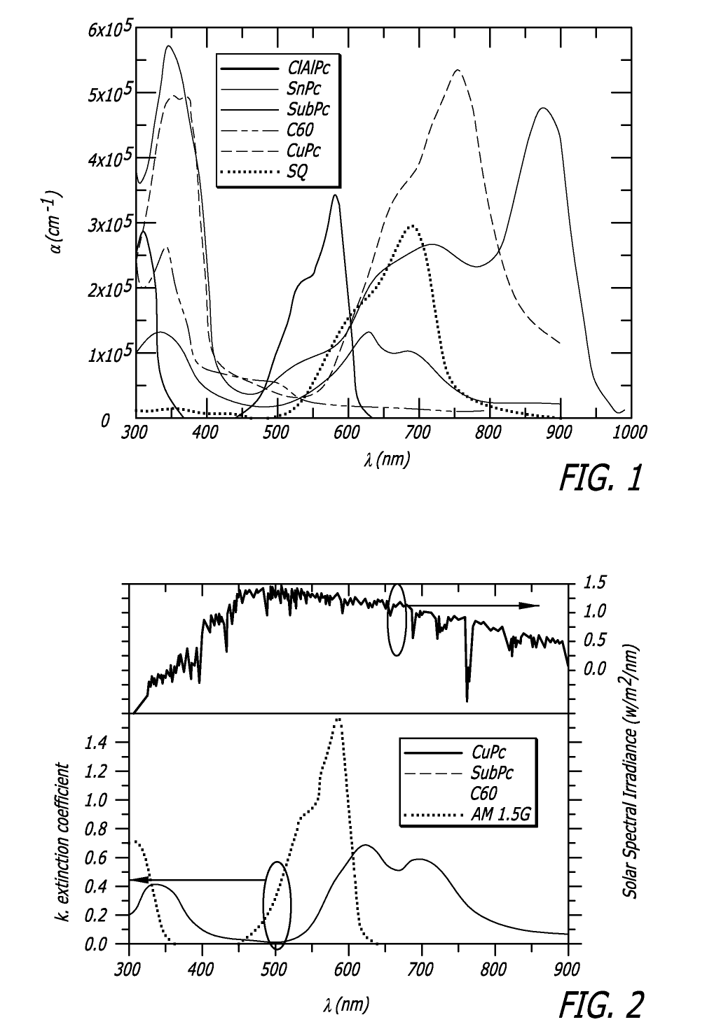

As shown in FIG. 1, the variety of absorption coefficients for organic semiconducting materials offers many possibilities for complementary absorption over the solar spectrum.

Various film morphologies can also be utilized within each subcell, including planar heterojunctions, bulk heterojunctions (BHJ), mixed heterojunctions (MHJ), and nanocrystalline bulk heterojunctions (ncBHJ). Examples of planar heterojunction devices are shown in Tables 1-3.

TABLE 3
Example structures for planar heterojunction
tandem solar cells incorporating mixed layers.

| Donor | Mixed | A | B | l | Donor | Mixed | A | B | C |
|---|---|---|---|---|---|---|---|---|---|
| SubPc | SubPc: C₆₀ | C₆₀ | PTCBl | Ag | CuPc | CuPc: C₆₀ | C₆₀ | BCP | Ag |
| | BHJ | | | | | BHJ | | | |
| SubPc | SubPc: C₆₀ | C₆₀ | BPhen | Au | CuPc | CuPc: C₆₀ | C₆₀ | BCP | Ag |
| | ncBHJ | | | | | ncBHJ | | | |
| SubPc | SubPc: C₇₀ | C₇₀ | BCP | WO3 | CuPc | CuPc: SnPc: C₆₀ | C₆₀ | BCP | Ag |
| | ncBHJ | | | | | ncBHJ | | | |
| SQ | SQ: C₆₀ | C₆₀ | BCP | MoO3 | DlP | DlP: C₇₀ | C₇₀ | BCP | Ag |
| | BHJ | | | | | BHJ | | | |

A = Acceptor layer
B = Blocking layer
C = Cathode
L = Charge transfer Layer or Charge Recombination Layer

Devices can be fabricated by vacuum thermal evaporation (VTE) and/or organic vapor phase deposition (OVPD). Doping of donor materials with high mobility materials such as pentacene may be another route to improved device performance.

Engineering of film crystallinity is also desired for optimal device performance. It has been suggested that exciton diffusion length (L_{D}) increases with increasing crystal size, while series resistance (R_{S}) decreases. This would allow active layer thicknesses to be increased proportionally, resulting in greater exciton dissociation and increased J_{SC}. Growth by OVPD has been shown to give increased control over film crystallinity in certain circumstances.

Due to the extremely large parameter space for design (layer order, layer material, layer thickness, number of layers, etc), certain parameters must be set before optical modeling can be performed to optimize the device. The first step is choice of photoactive materials, which are selected based on complimentary absorption wavelengths and high V_{oc} which has been demonstrated for individual devices. There is an inherent tradeoff in this selection, as materials which absorb longer wavelengths typically have a smaller optical gap and therefore create devices with lower V_{oc}. Next, upper- and lower-bounds for layer thicknesses must be set taking into account. Layers which are too thin will be discontinuous, creating leakage or parallel junctions, whereas layers which are too thick can increase the resistivity of devices and inhibit carrier transport. Once these parameters have been chosen, thicknesses can be optimized using the optical field model.

Tandem combination of organic solar cells with two subcells electrically coupled in series can be studied from an optical point of view and then unified with electrical models of charge generation and transport in the solar cells. For solar cells, there are three characteristics that effect the power conversion efficiency (ηₚ): short-circuit current (J_{SC}), V_{OC}, and fill factor (FF). J_{SC} is largely a function of two competing parameters: exciton diffusion length (L_{D}) and absorption coefficient (α). Film thickness is generally limited to 1-2 times L_{D} for current to be generated by exciton dissociation at the heterojunction interface. Values for L_{D} in organic materials are generally on the order of tens or hundreds of angstroms; however, the thickness required for absorption of all photons (given by 1/α) is generally on the order of thousands of angstroms.

In a series stacked solar cell, the J_{SC} generated by each subcell is generally equal at the operating illumination intensity to prevent the buildup of photogenerated charge. The photocurrent can be balanced by varying the thickness and order of the individual layers of the solar cells in the stack and considering the optical interference effects in the layers. V_{OC} typically is the sum of the voltages of the subcells. These parameters, along with experimentally measured values of L_{D} and α, are incorporated into a model utilizing the well-developed transfer matrix method to determine the optimal device structure. FIG. 2 shows optical constants measured for the active layers in some instances and their relation to the solar spectrum.

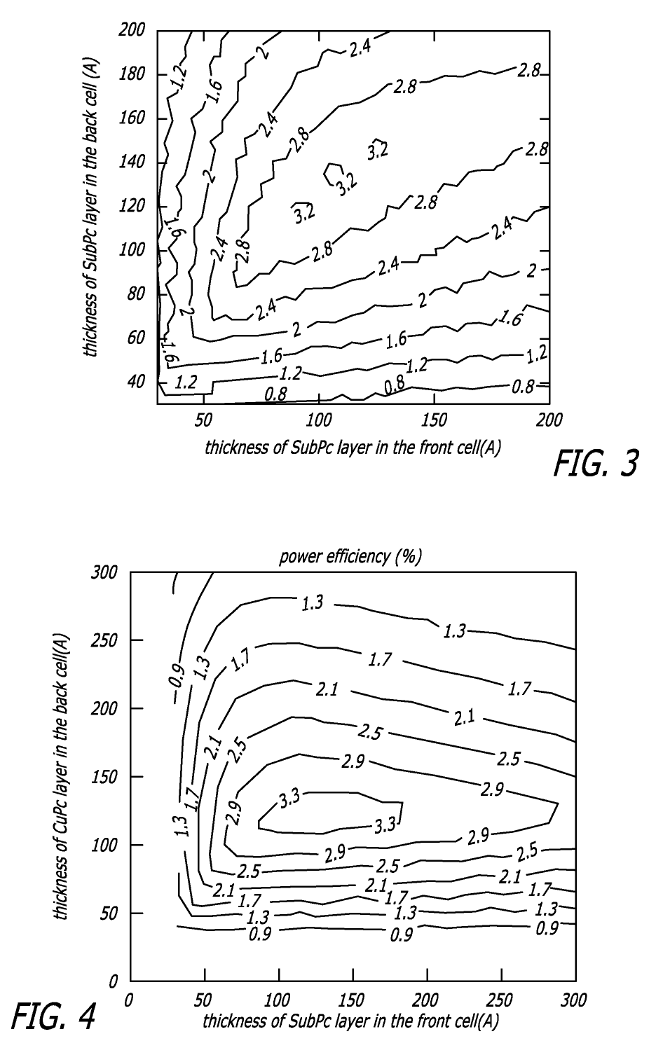

Several example planar heterojunction tandem devices have been modeled. For a tandem cell employed with a SubPc donor material in both the front cell and back cell, the prototype layer structure is the following: glass/1500 Å ITO/x₁ Å SubPc/x₂ Å C₆₀/5 Å Ag/y₁ Å SubPc/y₂ Å C₆₀/100 Å BCP/800 Å Al. The exemplified tandem cell has the following layer structure: glass/1500 Å ITO/105 Å SubPc/105 Å C₆₀/5 Å Ag/130 Å SubPc/130 Å C₆₀/100 Å BCP/800 Å Al, wherein the resulting J_{SC} is 3.3 mA/cm². The optimized efficiency is ηₚ=3.2% as shown in FIG. 3.

The terminology used herein, e.g., X₁ refers to the position and layers in each cell. For example, in “X₁” x represents the front cell, whereas the subscripts are the layers in that cell—here 1 represents the first layer. Similarly, y is the back cell. Therefore, for y₂ represents the back of the cell and the 2nd layer.

The tandem cell can also be modeled with a SubPc donor material in the front cell and a CuPc/C₆₀ back cell to enhance the visible spectrum absorption. As shown in FIG. 4, the exemplified tandem cell structure is the following: glass/1500 Å ITO/120 Å SubPc/120 Å C₆₀/5 Å Ag/110 Å CuPc/110 Å C₆₀/100 Å BCP/800 Å Ag, wherein the optimized J_{SC} is 4.2 mA/cm² and the efficiency ηₚ is 3.3%.

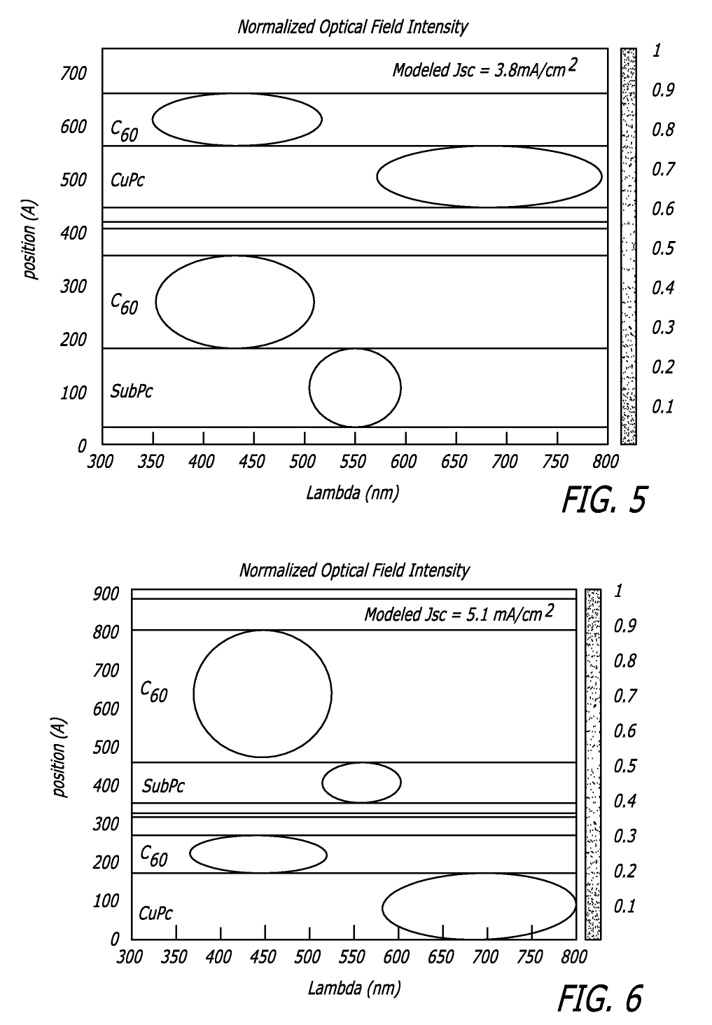

For a third tandem cell modeled with a SubPc donor material in the front cell and a CuPc back cell, the exemplified structure is the following: glass/1500 Å ITO/50 Å MoO₃/145 Å SubPc/180 Å C₆₀/50 Å PTCBI/10 Å Ag/25 Å MoO₃/120 Å CuPc/100 Å C₆₀/80 Å BCP/1 k Å Ag, wherein the resulting J_{SC} is 3.8 mA/cm². Assuming a FF of 0.60 and a V_{OC} of 1.43 V, the optimized ηₚ is 3.3%. FIG. 5 shows that the absorption regions for each material (circled) are not at the optical field maxima for those wavelengths.

Finally, a tandem cell utilizing CuPc in the front cell and SubPc in the back cell was modeled. The exemplified tandem cell is the following: glass/1500 Å ITO/175 Å CuPc/100 Å C₆₀/50 Å PTCBI/10 Å Ag/25 Å MoO₃/105 Å SubPc/345 Å C₆₀/80 Å BCP/1 k Å Ag, wherein the resulting J_{sc} is 5.1 mA/cm². Assuming a FF of 0.60 and a V_{oc} of 1.43 V, the optimized ηₚ is 4.4%. FIG. 6 shows the modeled optical field in this structure; the absorption regions are well-matched with the optical field.

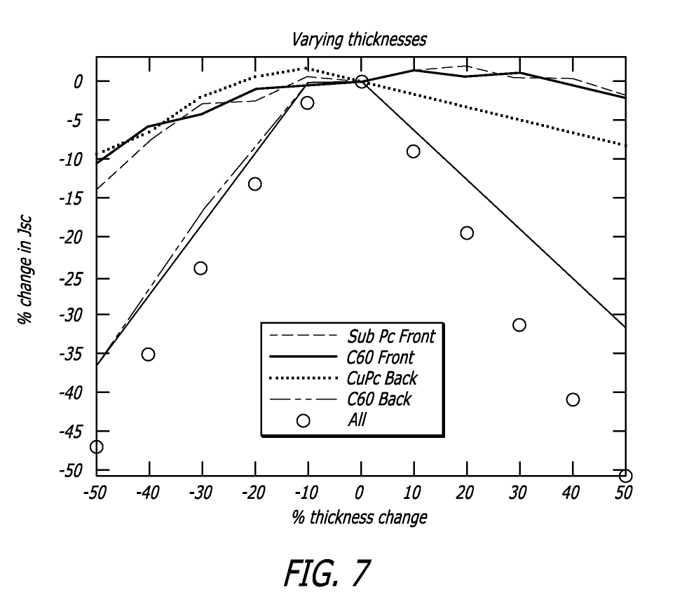

It is important to note that simply stacking two efficient solar cells will not necessarily result in an efficient tandem cell. Because of the complex optical interference and absorption bands of each layer, optical modeling is essential to achieve high efficiencies. The exemplified unoptimized tandem cell, designed using structures similar to the optimized CuPc/C₆₀ and SubPc/C₆₀ individual cells, is the following: glass/1500 Å ITO/20 Å NPD/120 Å SubPc/250 Å C₆₀/50 Å PTCBI/10 Å Ag/20 Å MoO₃/150 Å CuPc/400 Å C₆₀/100 Å BCP/1 k Å Al, wherein the resulting J_{sc} is 1.3 mA/cm². Assuming a FF of 0.60 and a V_{oc} of 1.43 V, the ηₚ is 1.3%. FIG. 7 shows the modeled result of the normalized change in J_{SC} as a result of changing the normalized thickness of the active layers in an optimized device. From this, it can be seen that for large variations in thickness, device performance decreases significantly, while for small variations (within experimental error) there are only small decreases.

A comparison of the performance of these devices is summarized in Table 4.

TABLE 4
Device performance of a modeled device of the following:
glass/1500 Å/ITO/175 Å CuPc/100 Å C₆₀/50 Å PTCBl/10
Å Ag/25 Å MoO₃/105 Å SubPc/345 Å C₆₀/80 Å BCP/1 k Å Ag.

| | Model J_{sc} | | | |
|---|---|---|---|---|
| Device | (mA/cm² | V_{oc} (V) | FF | ηₚ (%) |
| Optimized | 9.8 | 0.45 | 0.65 | 2.9 |
| CuPC/C₆₀ | | | | |
| Optimized | 5.9 | 0.97 | 0.57 | 3.2 |
| SubPc/C₆₀ | | | | |
| SubPc - Front | 3.8 | 1.43 | 0.60 | 3.3 |
| Tandem | | | | |
| SubPc - Back | 5.1 | 1.43 | 0.60 | 4.4 |
| Tandem | | | | |
| Unoptimized | 1.3 | 1.43 | 0.60 | 1.1 |
| Tandem | | | | |

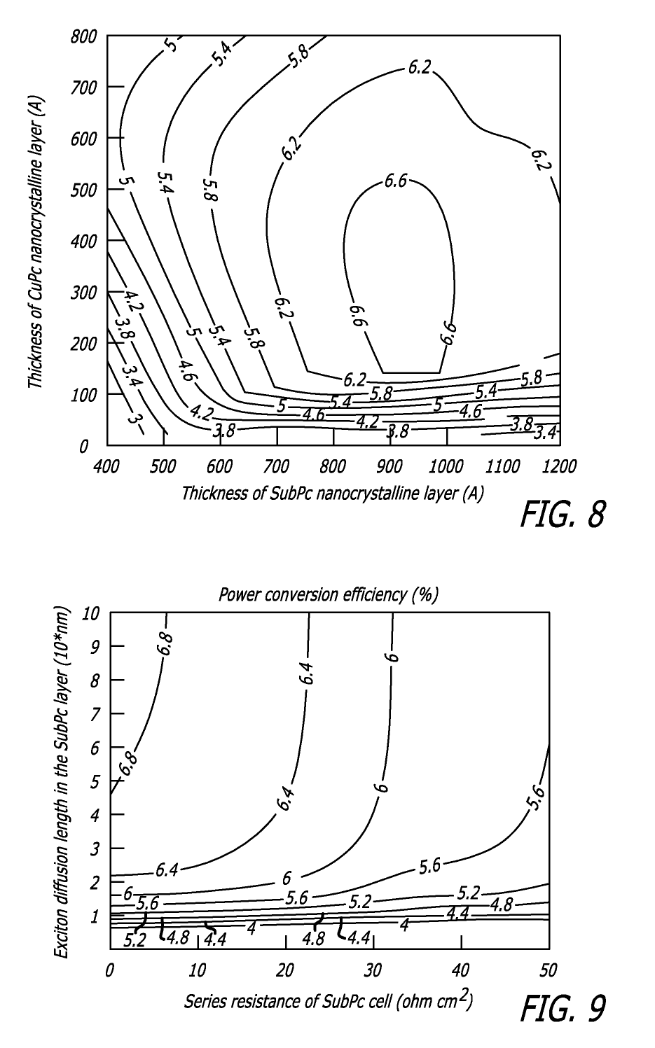

Nanocrystalline bulk heterojuntion (ncBHJ) CuPc:C₆₀ solar cells comprised of an ordered and interdigitated interface have previously been grown by organic vapor phase deposition. These devices were shown to significantly improve efficiency over otherwise identical planar heterojunction solar cells due to efficient exciton dissociation and low series resistance. By combining other nanocrystalline materials, it may be possible to model and fabricate very high efficiency solar cells. As an example, ncBHJ SubPc:C₆₀ and CuPc:C₆₀ have been modeled as two subcells in a tandem structure. Thus combining the ncBHJ cells with tandem cells using SubPc in the front cell and CuPc in the back cell, the exemplified tandem cell structure is the following: glass/1500 Å ITO/50 Å SubPc/950 Å SubPc:C₆₀ ncBHJ/400 Å C₆₀/5 Å Ag/100 Å CuPc/175 Å CuPc:C₆₀ ncBHJ/200 Å C₆₀/100 Å BCP/800 Å Ag, resulting in 6.6% maximum efficiency as shown in FIG. 8.

It is also possible, and sometimes desirable, to fabricate devices with increased crystallinity. Organic electronic device performance is relatively low compared to inorganic devices because of low diffusion lengths and high resistance due to highly disordered films. Without being bound by any theory, it is predicted that in more ordered films, these limitations will decrease. FIG. 9 shows a contour plot of efficiency versus. L_{D} and R_{S} for a SubPc/SubPc tandem cell similar to that of FIG. 3.

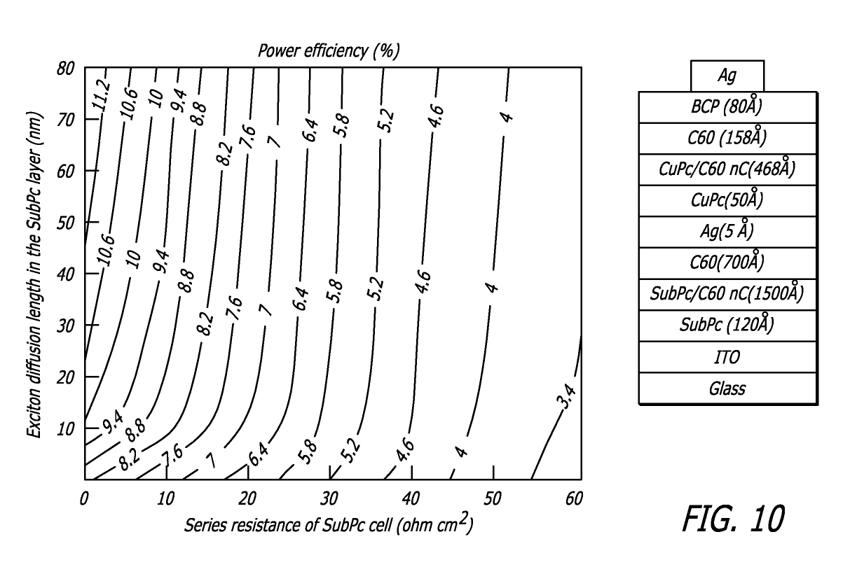

An idealized efficiency of 6.8% may be possible, more than double that of the amorphous structure. A similar plot for a SubPc:CuPc ncBHJ cell is shown in FIG. 10, with a resulting increase projected to be above 11% for the structure glass/1500 Å ITO/120 Å SubPc/1500 Å SubPc:C60 ncBHJ/700 Å C₆₀/5 Å Ag/50 Å CuPc/468 Å CuPc:C60 ncBHJ/158 Å C₆₀/80 Å BCP/1 k Å Ag. Highly ordered films have previously been demonstrated by the use of OVPD or structural templating.

### EXAMPLES

### Exemplary Device

With further reference to FIG. 10, for the bottom cell (which is close to the ITO anode side) SubPc/C60 nanocrystalline cell was used, with 120 Å SubPc deposited as a continuous wetting layer, followed by a nanocrystalline C60/SubPc multilayer with thickness of 1500 Å deposited on top of the original SubPc wetting layer. Next, 700 Å of C60 layer was applied to finish the front cell. For the intermediate layer, Ag was used as a recombination center to balance the photocurrent generated in the front and back cell.

The top cell (which is close to the Ag cathode side) is CuPc/C60 nanocrystalline cell, with 50 Å CuPc as continuous wetting layer deposited thereon. A nanocrystalline C60/CuPc multilayer with thickness of 468 Å on top of the original CuPc wetting layer, followed with 158 Å C60 donor layer and 80 ÅBCP blocking layer. The metal Ag used as a cathode.

Other Devices

An initial set of tandem devices was fabricated by vacuum thermal evaporation. At a base pressure <5×10⁻⁷ Torr, films were deposited at 1 Å/s onto glass precoated with indium doped tin oxide (ITO) (Präzisions Glas & Optik GmbH, Germany). The charge recombination layer consisted of metal nanoclusters, was deposited at 0.5 Å/s, and the metal cathodes were deposited through a circular shadow mask of 1 mm in diameter. I-V and power efficiency were measured using a Oriel 150 W solar simulator with AM1.5G filters, and external quantum efficiency (EQE) was measured using a monochromated beam of light from an Xe source chopped at 400 Hz. Light intensity was measured utilizing an National Renewable Energy Laboratory-calibrated solar cell, and photocurrent spectra was measured using a lock-in amplifier.

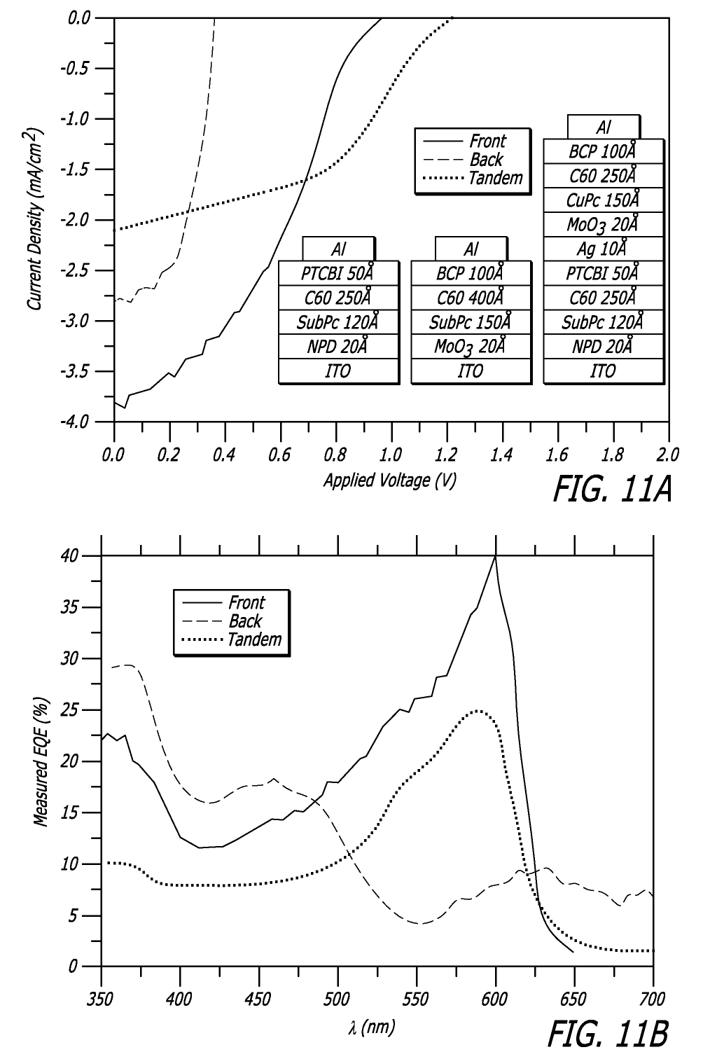

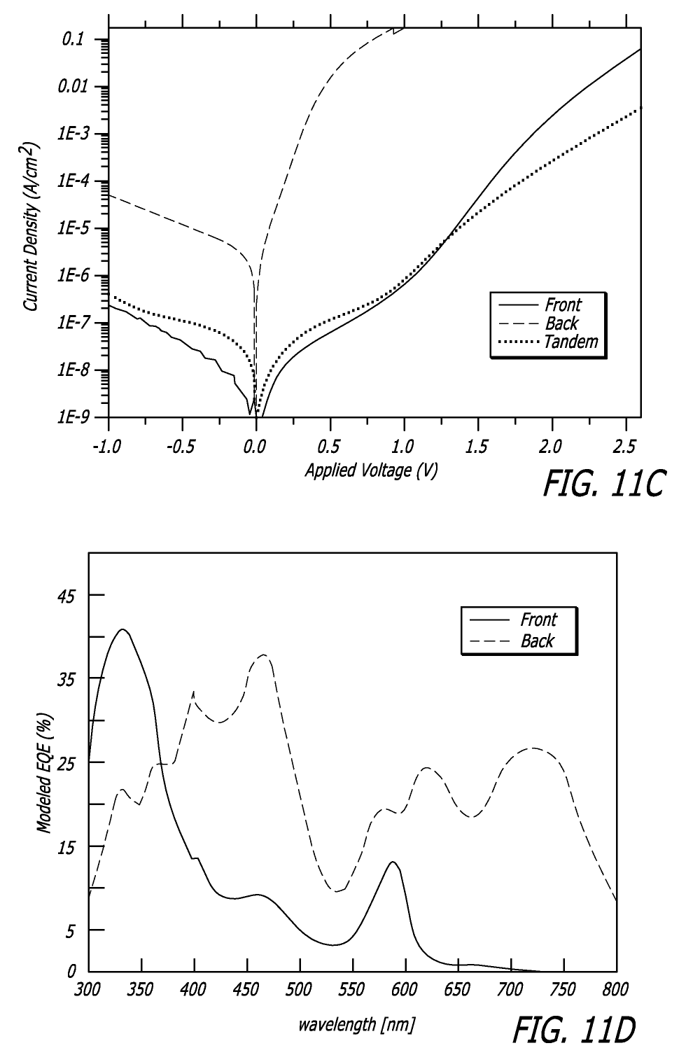

The first device presented is an unoptimized tandem with the structure glass/1500 Å ITO/20 Å NPD/120 Å SubPc/250 Å C₆₀/50 Å PTCBI/10 Å Ag/20 Å MoO₃/150 Å CuPc/400 Å C₆₀/100 Å BCP/1 k Å Al, wherein the measured J_{sc} is 2.1 mA/cm², FF is 0.45, V_{oc} is 1.24 V, resulting in ηₚ is 1.16±0.02%. The device characteristics are shown in FIG. 11. Table 5 compares the performance of the front, back, and tandem cells, showing that for a non-optimized tandem the resulting device has significantly lower J_{sc} than the individual cells.

TABLE 5
Device performance of an experimentally grown device of the following:
glass/1500 Å ITO/20 Å NPD/120 Å SubPc/250 Å C₆₀/50 Å PTCBl/10
Å Ag/20 Å MoO₃/150 Å CuPc/400 Å C₆₀/100 Å BCP/1 k Å Al

| Device | ηₚ (%) | V_{oc} (V) | FF | J_{sc} (mA/cm²) | Model J_{sc} |
|---|---|---|---|---|---|
| Back Only | 0.54 ± 0.01 | 0.36 | 0.54 | 2.8 | 6.0 |
| Front Only | 1.39 ± 0.01 | 0.96 | 0.38 | 3.9 | 4.4 |
| Tandem | 1.16 ± 0.02 | 1.24 | 0.45 | 2.1 | 1.3 |

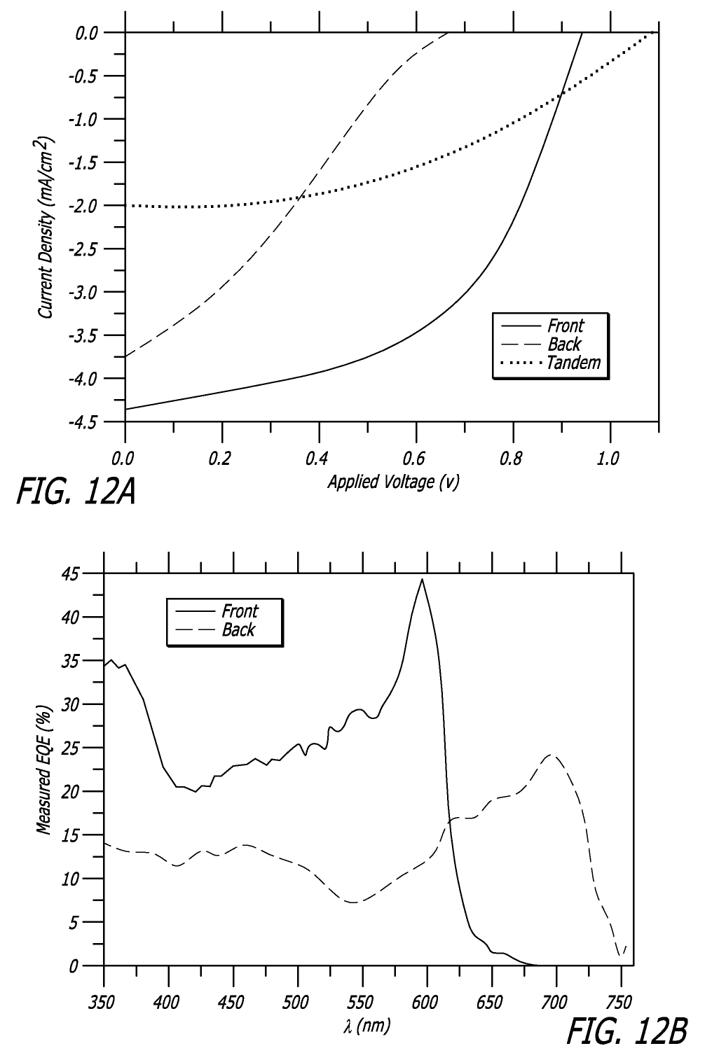

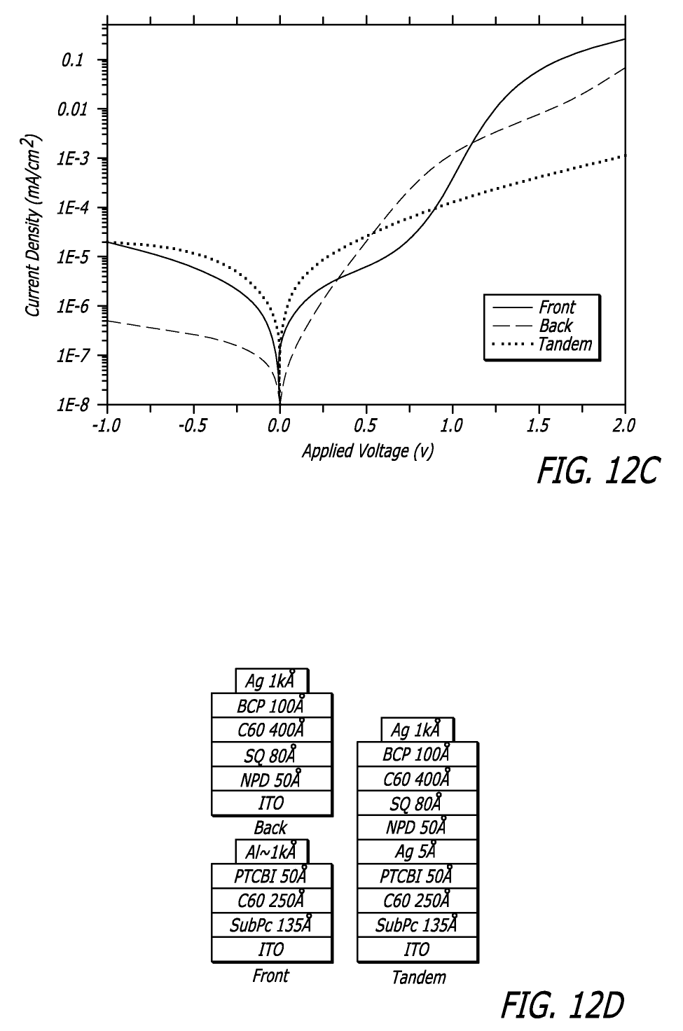

The second device presented is an unoptimized tandem with the structure glass/1500 Å ITO/135 Å SubPc/250 Å C₆₀/50 Å PTCBI/5 Å Ag/50 Å NPD/80 Å SQ/400 Å C₆₀/100 Å BCP/1 k Å Ag, wherein the measured J_{sc} is 2.1 mA/cm², FF is 0.44, V_{OC} is 1.11 V, resulting in ηₚ is 1.00±0.02%. The device characteristics are shown in FIG. 12. Table 6 compares the performance of the front, back, and tandem cells, showing that for a non-optimized tandem the resulting device has significantly lower J_{sc} than the individual cells.

TABLE 6
Device performance of an experimentally grown device of the following:
glass/1500 Å ITO/135 Å SubPc/250 Å C₆₀/50 Å PTCBl/5
Å Ag/50 Å NPD/80 Å SQ/400 Å C₆₀/100 Å BCP/1 k Å Ag

| Device | ηₚ (%) | V_{oc} (V) | FF | J_{sc} (mA/cm²) |
|---|---|---|---|---|
| Back Only | 0.71 ± 0.01 | 0.66 | 0.29 | 3.7 |
| Front Only | 2.12 ± 0.09 | 0.93 | 0.53 | 4.3 |
| Tandem | 1.00 ± 0.02 | 1.11 | 0.44 | 2.1 |

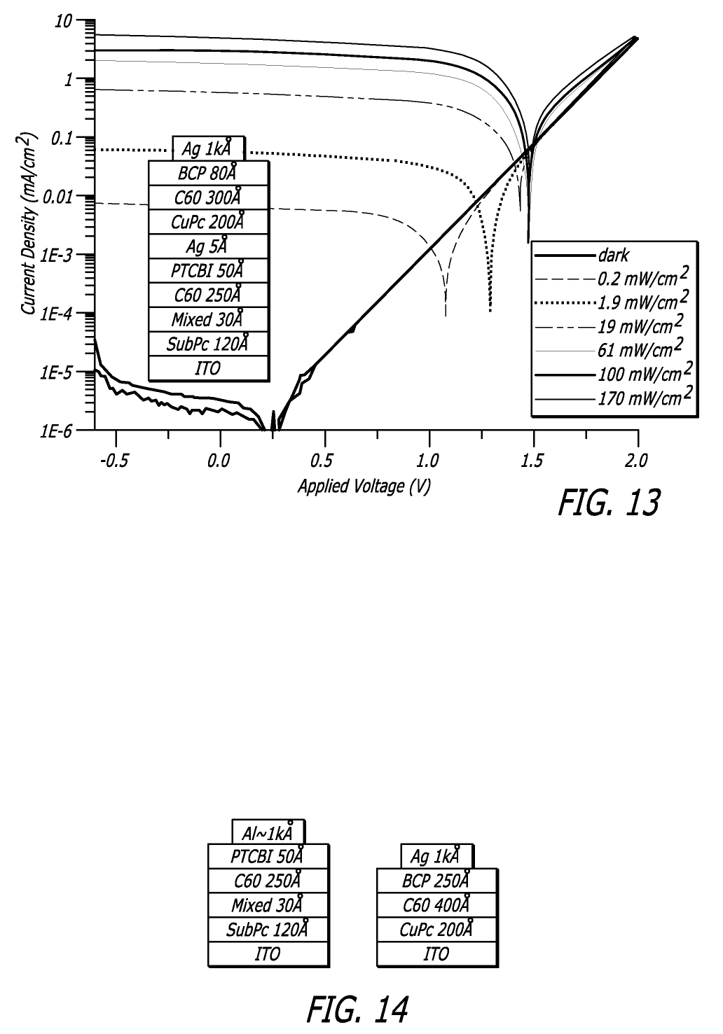

The third device presented is an optimized tandem with a SuPc front cell and a CuPc back cell. FIG. 13 shows the tandem device structure: glass/150 nm ITO/120 Å SubPc/30 Å SubPc:C₆₀ 1:1/200 Å C₆₀/50 Å PTCBI/5 Å Ag nanoclusters/200 Å CuPc/300 Å C₆₀/80 Å BCP/1 kÅ Ag, along with J-V curves at varying light intensities.

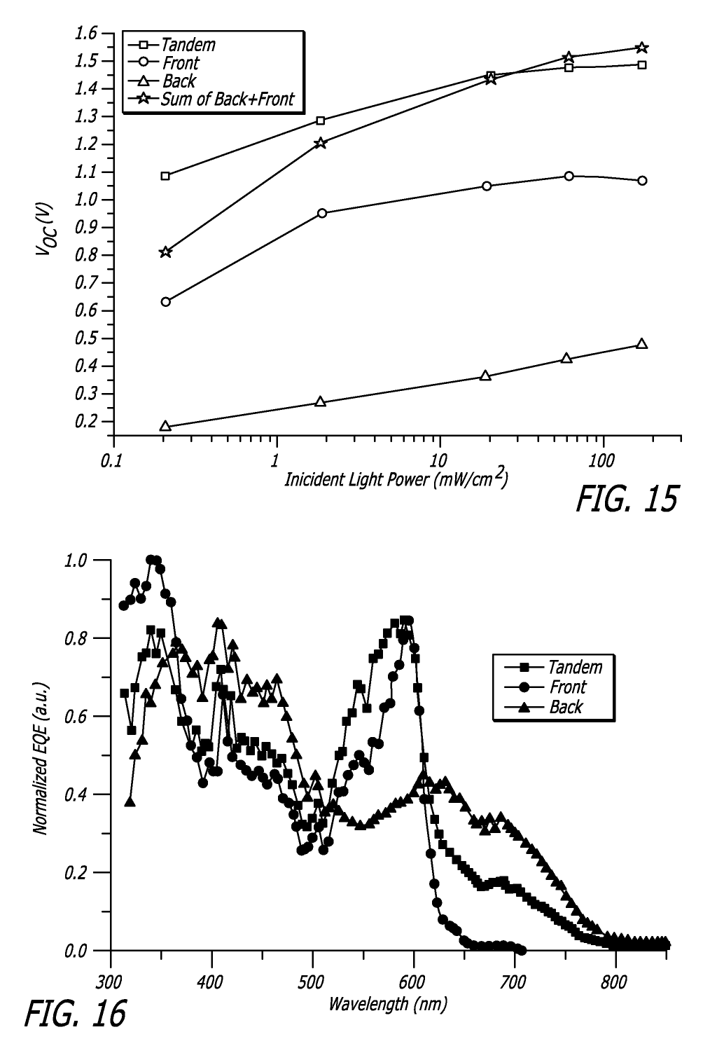

FIG. 14 shows the structure of front and back cells for comparison. Compared to the individual subcells, the V_{OC} of the tandem is shown to be close to the sum of individual cells (1.47 V versus 0.45 V for CuPc/C₆₀ and 1.08 V for SubPc/C₆₀ at 1 sun), as shown in FIG. 15.

Normalized EQE data in FIG. 16 shows that both CuPc and SubPc are contributing to the photocurrent, with SubPc's high peak between 500 and 600 nm and CuPc's broad shoulder beyond 650 nm both present.

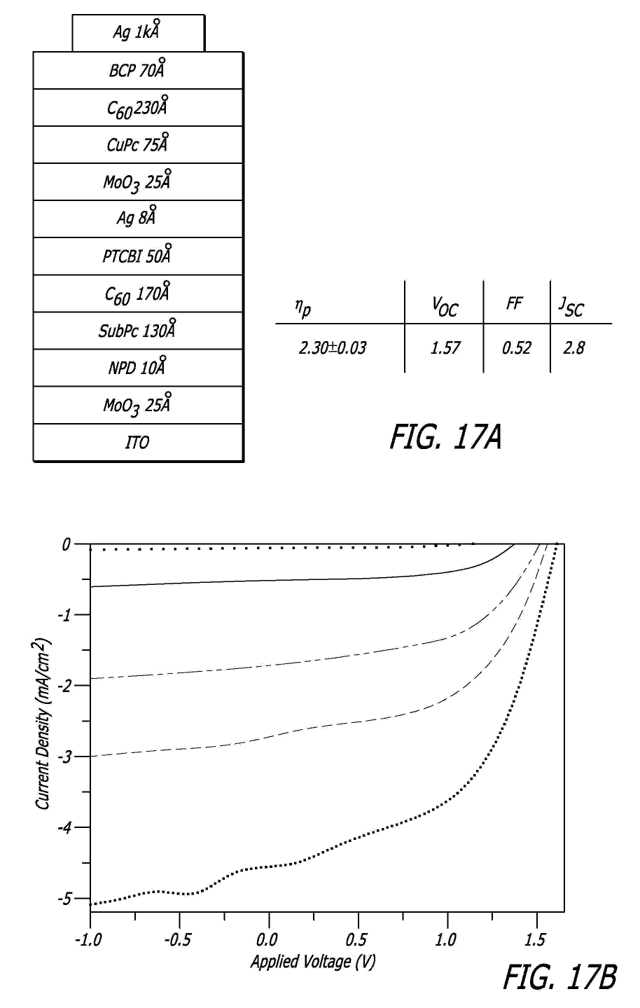

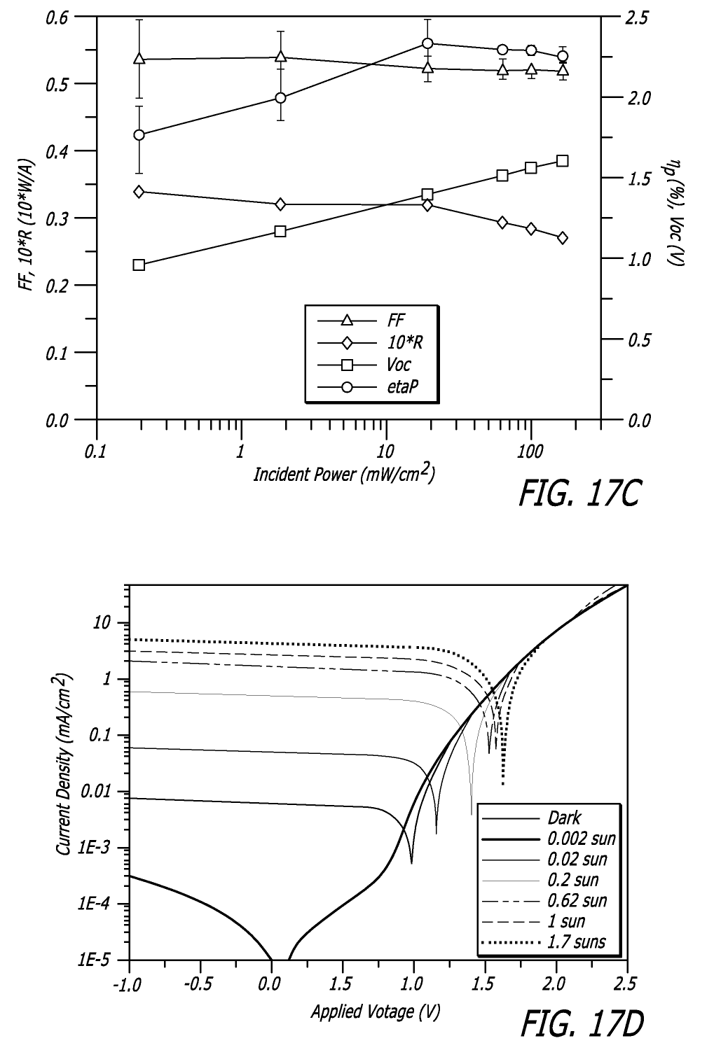

The fourth device is an optimized tandem with a SubPc front cell and a CuPc back cell. FIG. 17 shows the tandem device structure: glass/1500 Å ITO/25 Å MoO₃/10 Å NPD/130 Å Su Pc/170 Å C₆₀/50 Å PTCBI/8 Å Ag/25 Å MoO₃/75 Å CuPc/230 Å C₆₀/70 Å BCP/1 k Å Ag, along with the J-V curves at various light intensities.

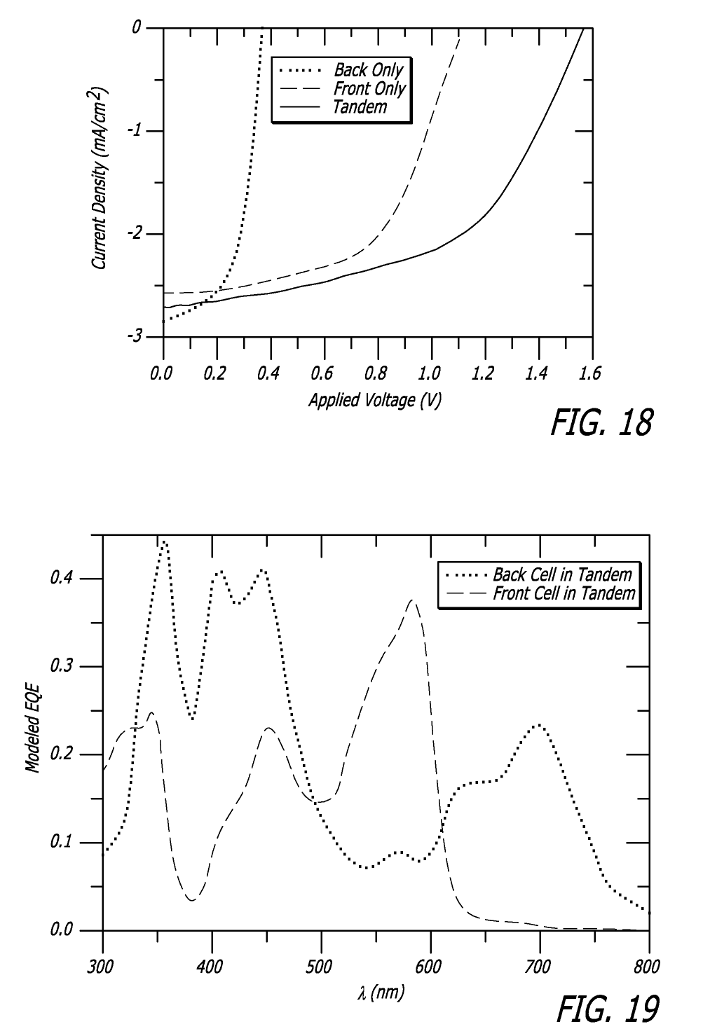

FIG. 18 shows the J-V characteristic of front and back cells for comparison. Compared to the individual subcells, the V_{OC} of the tandem cell is shown to be close to the sum of individual cells (1.57 V versus 0.38 V for CuPc/C₆₀ and 1.12 V for SubPc/C₆₀ at 1 sun).

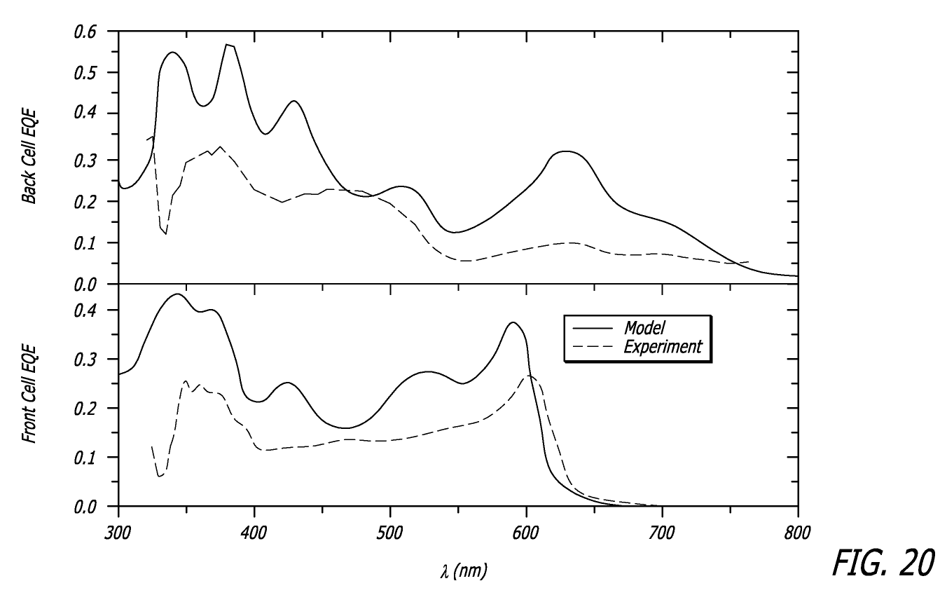

The modeled EQE for this structure in FIG. 19 shows that the spectral gap in the CuPc/C₆₀ back cell is filled by the SubPc/C₆₀ front cell. FIG. 20 compares the experimental and modeled EQE for the individual front and back cells. Although the performance is of these devices is lower than the modeled values (likely due to contamination in the growth process), this data shows that a well-designed tandem device can perform as well as the sum as the individual cells. Device performance is shown in Table 7.

TABLE 7
Device performance of an experimentally grown device of the following:
glass/1500 Å ITO/25 Å MoO₃/10 Å NPD/130 Å SuPc/170 Å C₆₀/50
Å PTCBl/8 Å Ag/25 Å MoO₃/75 Å CuPc/230 Å C₆₀/70 Å BCP/1 k Å Ag

| Device | ηₚ (%) | V_{oc} (V) | FF | J_{sc} (mA/cm²) | Model J_{sc} |
|---|---|---|---|---|---|
| Back Only | 0.66 ± 0.04 | 0.38 | 0.59 | 2.9 | 5.7 |
| Front Only | 1.67 ± 0.01 | 1.12 | 0.55 | 2.7 | 3.7 |
| Tandem | 2.30 ± 0.03 | 1.57 | 0.52 | 2.8 | 3.2 |

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present invention.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. An organic photovoltaic device comprising two or more organic photoactive regions located between a first electrode and a second electrode,
wherein each of said organic photoactive regions comprise a donor, and an acceptor, and wherein said organic photovoltaic device comprises at least one exciton blocking layer, and at least one charge recombination layer, or charge transfer layer between the two or more photoactive regions.

2. The organic photovoltaic device according to claim 1, wherein at least one electrode comprises transparent conducting oxides or transparent conducting polymers.

3. The organic photovoltaic device according to claim 2, wherein the conducting oxides are chosen from indium tin oxide (ITO), tin oxide (TO), gallium indium tin oxide (GITO), zinc oxide (ZO), and zinc indium tin oxide (ZITO), and the transparent conductive polymers comprise polyanaline (PANI).

4. The organic photovoltaic device according to claim 1, wherein at least one of said electrodes is a cathode that comprises a metal substitute, a non-metallic material or a metallic material chosen from Ag, Au, Ti, Sn, and Al.

5. The organic photovoltaic device according to claim 1, wherein the charge recombination layer, or charge transfer layer is comprised of Al, Ag, Au, MoO₃, Li, Li F, Sn, Ti, WO₃, indium tin oxide (ITO), tin oxide (TO), gallium indium tin oxide (GITO), zinc oxide (ZO), or zinc indium tin oxide (ZITO).

6. The organic photovoltaic device according to claim 5, wherein the charge recombination layer, or charge transfer layer is composed of metal nanoclusters, nanoparticles, or nanorods.

7. The organic photovoltaic device according to claim 1, wherein said donor is chosen from subphthalocyanine (SubPc), copper phthalocyanine (CuPc), chloroaluminium phthalocyanine (ClAlPc), tin phthalocyanine (SnPc), pentacene, tetracene, diindenoperylene (DIP), and squaraine (SQ).

8. The organic photovoltaic device of claim 7, wherein the squaraine compound is chosen from 2,4-Bis [4-(N,N-dipropylamino)-2,6-dihydroxyphenyl; 2,4-Bis[4-(N,N-diisobutylamino)-2,6-dihydroxyphenyl; and salts thereof.

9. The organic photovoltaic device according to claim 1, wherein each of said organic photoactive regions comprise a donor that exhibits complementary absorption ranges with the donor of at least one other organic photoactive region.

10. The organic photovoltaic device according to claim 1, wherein the acceptor is chosen from C₆₀, C₇₀, 3,4,9,10-perylenetetracarboxylicbis-benzimidazole (PTCBI), Phenyl-C₆₁-Butyric-Acid-Methyl Ester ([60]PCBM), Phenyl-C₇₁-Butyric-Acid-Methyl Ester ([70]PCBM), Thienyl-C₆₁-Butyric-Acid-Methyl Ester ([60]ThCBM), and hexadecafluorophthalocyanine (F₁₆CuPc).

11. The organic photovoltaic device according to claim 1, wherein the exciton blocking layer is chosen from bathocuproine (BCP), bathophenanthroline (BPhen), 3,4,9,10-perylenetetracarboxylicbis-benzimidazole (PTCBI), 1,3,5-tris(N-phenylbenzimidazol-2-yl)benzene (TPBi), tris(acetylacetonato) ruthenium(III) (Ru(acaca)₃), and aluminum(III) phenolate (Alq₂ OPH).

12. The organic photovoltaic device according to claim 1, wherein at least one of the at least two photoactive regions comprises a donor-acceptor heterojunction formed by a planar, bulk, mixed, hybrid-planar-mixed or nanocrystalline bulk heterojunction.

13. The organic photovoltaic device according to claim 12, wherein the heterojunction comprises mixtures of two or more materials chosen from: subphthalocyanine (SubPc), C₆₀, C₇₀, squaraine, copper phthalocyanine (CuPc), tin phthalocyanine (SnPc), and diindenoperylene (DIP).

14. The organic photovoltaic device according to claim 13, wherein the mixtures comprise:
subphthalocyanine (SubPc)/C₆₀;
subphthalocyanine (SubPc)/C₇₀;
squaraine/C₆₀;
copper phthalocyanine (CuPc)/C₆₀;
copper phthalocyanine (CuPc)/tin phthalocyanine (SnPc)/C₆₀; or
diindenoperylene (DIP)/C₇₀;
aluminum-chlorophthalocyanine (AlClPc)/C₆₀; and
aluminum-chlorophthalocyanine (AlClPc)/C₇₀.

15. The organic photovoltaic device according to claim 1, wherein at least one of the photoactive layers further comprises a buffer.

16. The organic photovoltaic device according to claim 15, wherein the buffer is MoO₃.

17. The organic photovoltaic device according to claim 1, wherein at least one organic layer is deposited by vacuum thermal evaporation, organic vapor-jet printing or organic vapor phase deposition.

18. The organic photovoltaic device according to claim 1, wherein at least one organic layer is deposited by a solution processing approach chosen from doctor-blade, spin coating, and inkjet printing.

19. The organic photovoltaic device according to claim 1, wherein the donor is doped with a high mobility material.

20. The organic photovoltaic device according to claim 19, wherein the high mobility material comprises pentacene.

21. The organic photovoltaic device according to claim 17, wherein thickness of the organic layers ranges from 25-1200 \acute{Å}.

22. The organic photovoltaic device according to claim 1, wherein at least one organic layer is crystalline.

23. The organic photovoltaic device according to claim 22, wherein the organic layer is crystalline over a range from 10 nm to 1 cm.

24. The organic photovoltaic device according to claim 1, wherein the device displays an open-circuit voltage (V_{oc}) in a range up to 2.2 V.

25. The organic photovoltaic device according to claim 1, wherein the device displays a power efficiency (ηₚ) greater than 2%.

26. The organic photovoltaic device according to claim 25, wherein the modeled device displays a power efficiency (ηₚ) greater than 10%.

27. The organic photovoltaic device of claim 1, wherein said device comprises three or more organic photoactive regions, each of said organic photoactive regions comprising a donor and an acceptor, said device further comprising at least one exciton blocking layer, charge recombination layer, or charge transfer layer, and optionally comprising a buffer layer.

28. A method for producing an organic photovoltaic device, said method comprising:
depositing a first electrode onto a substrate;
depositing a first photoactive region onto the first electrode;
depositing a first charge recombination layer, or charge transfer layer onto the first photoactive region;
depositing a second photoactive region onto the first charge recombination layer, or charge transfer layer; and
depositing a second electrode onto the second photoactive region;
wherein the first organic photoactive region comprises a first donor and a first acceptor,
wherein the second organic photoactive region comprises a second donor and a second acceptor,
wherein an exciton blocking layer is deposited over at least one photoactive region and
wherein a charge recombination layer, charge transfer layer, or electrode is deposited between each photoactive region.

29. A method for generating and/or measuring electricity or an electric signal, said method comprising providing light to the organic photovoltaic device of claim 1.

30. An organic photovoltaic device comprising two or more organic photoactive regions located between a first electrode and a second electrode,
wherein each of said organic photoactive regions comprise:
a donor comprising a material chosen from subphthalocyanine (SubPc), copper phthalocyanine (CuPc), chloroaluminium phthalocyanine (ClAlPc), tin phthalocyanine (SnPc), pentacene, tetracene, diindenoperylene (DIP), squaraine (SQ), zinc phthalocyanine (ZnPc), and lead phthalocyanine (PbPc);
an acceptor comprising a material chosen from C₆₀, C₇₀, 3,4,9,10-perylenetetracarboxylicbis-benzimidazole (PTCBI), Phenyl-C₆₁-Butyric-Acid-Methyl Ester, ([60]PCBM), Phenyl-C₇₁-Butyric-Acid-Methyl Ester ([70]PCBM), Thienyl-C₆₁-Butyric-Acid-Methyl Ester ([60]ThCBM), and hexadecafluorophthalocyanine (F₁₆CuPc);
an exciton blocking layer comprising a material chosen from WO₃, MoO₃, bathocuproine (BCP), bathophenanthroline (BPhen), 3,4,9,10-perylenetetracarboxylicbis-benzimidazole (PTCBI), and 1,3,5-tris(N-phenylbenzimidazol-2-Abenzene (TPBi),
a charge recombination layer, or charge transfer layer comprising a material chosen from Al, Ag, Au, MoO₃, and WO₃, and optionally a buffer layer comprising MoO₃,
wherein at least one of said electrodes is an anode that comprises indium tin oxide (ITO) and at least one of said electrodes is a cathode that comprises a material chosen from Ag, Au, and Al.
